(19) United States
(12) Patent Application Publication
(10) Pub. No.: US 2012/0118368 A1
(43) Pub. Date: May 17, 2012

(54) Method for Increasing the Efficiency of Organic Photovoltaic Cells

(75) Inventors: Jinsong Huang, Lincoln, NE (US); Yongbo Yuan, Lincoln, NE (US)

(73) Assignee: BOARD OF REGENTS OF THE UNIVERSITY OF NEBRASKA, Lincoln, NE (US)

(21) Appl. No.: 13/099,082

(22) Filed: May 2, 2011

Related U.S. Application Data
(60) Provisional application No. 61/329,873, filed on Apr. 30, 2010.

(51) Int. Cl. H01L 51/44; H01L 51/48

(52) U.S. Cl. 136/256; 438/82; 257/E51.026

(57) ABSTRACT

The present invention is directed to an organic photovoltaic cell that contains one or more dipole regions generally disposed between an organic active region and the electrodes and a process for producing such an organic photovoltaic cell.

### CROSS-REFERENCE TO RELATED APPLICATIONS

The present application is non-provisional application claiming the benefit of U.S. Provisional Application No. 61/329,873, filed Apr. 30, 2010, which is incorporated herein by reference in its entirety.

### FIELD OF THE INVENTION

The present invention relates to organic photovoltaic cells, and more particularly organic photovoltaic cells that comprise one or more dipole regions to increase the power conversion efficiency of the cells.

### BACKGROUND OF THE INVENTION

A significant fraction of the carbon released into the atmosphere is a result of burning coal and natural gas to produce electricity. Burning coal generates an especially large amount of CO₂ because of its high carbon content. It is, therefore, highly desirable to find ways to generate electricity without releasing carbon. The sun deposits 120,000 terawatts (TW) of power onto the Earth's surface, which is more than enough to provide the 13 TW of total power currently used by the planet's population or the 30 TW that is projected to be needed by 2050. The development of affordable photovoltaic (solar) cells is, therefore, one of the most promising long-term environmental and energy solutions.

Currently, almost all photovoltaic (PV) cells being manufactured are made of crystalline silicon. These cells have a power conversion efficiency (PCE) of 10-20%, cost $350/m² and have a useful lifespan of 30 years or longer. Over the lifetime of the cells, the average cost of the electricity that is generated in a sunny location is approximately $0.20/kW-hr, which is four times more than the typical cost of electricity from burning fossil fuels.

In contrast to silicon PV cells, organic photovoltaic cells, including small organic molecule and polymer cells, are promising candidates due to their low material and processing costs and their mechanical flexibility. But their power conversion efficiency is currently significantly below that of silicon PV cells—about 4-7% compared to about 20%. This, despite the fact that much research has been performed on organic photovoltaic cells to improve their performance by increasing (a) light absorption via, for example, tuning the bandgap of the materials, using thicker films, tandem structures, or optical spacers, (b) charge transfer between donor and acceptor, and (c) charge carrier mobility of the materials. Thus, a need exists to improve the performance of organic photovoltaic cells.

### SUMMARY OF THE INVENTION

The present invention is directed to an organic photovoltaic cell comprising: (a) a cathode; (b) an anode; (c) an organic active region for absorbing photons and generating excitons disposed between the cathode and the anode; and (d) (i) a cathode dipole region generally disposed between the organic active region and the cathode, wherein the cathode dipole region exhibits a positive charge near the organic active region; (ii) an anode dipole region generally disposed between the organic active region and the anode, wherein the anode dipole region exhibits a negative charge near the organic active region; or (iii) both (i) and (ii).

The present invention is also directed to an organic photovoltaic cell comprising: (a) a cathode; (b) an anode; (c) a heterogenic organic active region disposed between the cathode and the anode that comprises a mixture of an electron acceptor material and an electron donor; and (d) an anode dipole region generally disposed between the organic active region and the anode that comprises permanent dipole nanorods aligned and fixed in an anode-dipole-region cross-linked matrix that comprises a hole transport material so that the anode dipole region exhibits a negative charge near the organic active region.

Further, the present invention is directed to an organic photovoltaic cell comprising: (a) a cathode; (b) an anode; (c) a heterogenic organic active region disposed between the cathode and the anode that comprises a mixture of an electron acceptor material and an electron donor; (d) a cathode dipole region generally disposed between the organic active region and the cathode, wherein cathode dipole region comprises a cathode-dipole-region ferroelectric polymer the molecules of which are aligned and fixed so that cathode dipole region exhibits a positive charge near the organic active region; and (e) an anode dipole region generally disposed between the organic active region and the anode, wherein the anode dipole region comprises an anode-dipole-region ferroelectric polymer the molecules of which are aligned and fixed so that the anode dipole region exhibits a negative charge near the organic active region.

Still further, the present invention is directed to an organic photovoltaic cell comprising: (a) a cathode; (b) an anode; (c) a heterogenic organic active region disposed between the cathode and the anode that comprises a mixture of an electron acceptor material and an electron donor; (d) a cathode dipole region generally disposed between the organic active region and the cathode, wherein cathode dipole region comprises cations dispersed within a cathode dipole region polymer, wherein the cations are sufficiently large so as to be essentially immobile at temperatures below the glass transition temperature of the cathode-dipole-region polymer so that cathode dipole region exhibits a positive charge near the organic active region; and (e) an anode dipole region generally disposed between the organic active region and the anode, wherein the anode dipole region comprises anions dispersed within an anode dipole region polymer, wherein the anions are sufficiently large so as to be essentially immobile at temperatures below the glass transition temperature of the anode-dipole-region polymer so that the anode dipole region exhibits a negative charge near the organic active region.

The present invention is also directed to a process of making an organic photovoltaic cell that comprises a cathode; an anode; an organic active region for absorbing photons and generating excitons disposed between the cathode and the anode; and a cathode dipole region generally disposed between the organic active region and the cathode, wherein the cathode dipole region exhibits a positive charge near the organic active region or an anode dipole region generally disposed between the organic active region and the anode, wherein the anode dipole region exhibits a negative charge near the organic active region, or both the cathode dipole region and the anode dipole region. The process comprises forming the dipole region(s) by delivering permanent dipoles, applying an electric field to the permanent dipoles to align the permanent dipoles, and fixing the position of the aligned permanent dipoles.

### BRIEF DESCRIPTION OF THE DRAWINGS

FIG. 1 depicts formation of an anode dipole region of the present invention that comprises permanent dipole nanorods in an organic matrix being aligned with an applied electric field and fixed in position by cross-linking the organic matrix by a thermal treatment.

FIG. 2 depicts an organic photovoltaic cell of the present invention that comprises an anode dipole region that comprises permanent dipole nanorods aligned and fixed in a cross-linked organic matrix.

FIG. 3(a) depicts an organic photovoltaic cell of the present invention that comprises a cathode dipole region and an anode dipole region, wherein each of said dipole regions comprises an aligned and fixed ferroelectric polymer; FIG. 3(b) depicts an anode dipole region that comprises a multiplicity of discontinuous deposits (nanomesas, or stacks of nanomesas); and FIG. 3(c) depicts an anode dipole region that is substantially continuous.

FIG. 4 depicts formation of a cathode dipole region of the present invention, wherein (a) depicts ions being moved to their respective dipole region upon application of an electric field and elevation of temperature and (b) depicts the fixed position of the anions after reduced temperature.

FIG. 5 is a graph of the current-voltage output of a conventional OPV, and OPV having a region that comprises an unaligned ferroelectric polymer between the cathode and the active region, and an OPV with an anode dipole region formed upon the alignment of fixing of the ferroelectric polymer.

FIG. 6 is a graph of the current-voltage output of conventional OPV and an OPV with an anode dipole region formed upon the alignment of fixing of the ferroelectric polymer as cast and after thermal treatment.

FIG. 7 is a graph of the current-voltage curves (AM, 100 mW/cm²) of regular OPVs devices, and devices with different numbers of polarized LB-deposed ferroelectric polymer monolayers.

FIG. 8 is a graph of the current-voltage curves for devices with differing ionic accumulation for an OPV comprising a cathode dipole region that comprises cations and an anode dipole region that comprises anions.

### DETAILED DESCRIPTION OF THE INVENTION

A typical organic photovoltaic (OPV) cell comprises one or more layers of organic materials positioned between a transparent indium tin oxide (ITO) anode coated on glass and a metal cathode of Mg, Al, Ca, or their alloys. Due to the high exciton binding energy (0.1-0.4 eV) in organic materials, photo-generated excitons can't be split by the weak built-in electric field. A donor-acceptor type heterojunction is generally formed in the OPV cell to split excitons. The energy conversion efficiency (η) of a solar cell, defined by the electric energy output divided by the solar energy (I_{light}) it absorbs, is expressed as:

η=I_{sc}V_{oc}FF/I_{light};

wherein I_{sc} is the short circuit current, V_{oc} is the open circuit voltage, and FF is the fill factor.

More specifically, the external quantum efficiency of an OPV device is the product of efficiencies in four steps of its operation: (1) light absorption by donor and acceptor molecules (η_{LA}); (2) exciton diffusion to donor/acceptor interface (η_{ED}); (3) charge transfer efficiency between donor and acceptor (η_{CT}); and (4) charge collection by electrode (η_{CL}). In most OPV cells, there is a fundamental tradeoff between the light absorption (η_{LA}) and the charge collection (η_{CL}) factors. For example, in order to maximize η_{LA}, most conjugated polymers need to have a thickness of at least 100 nm to completely absorb the sun light of energy higher than the polymers’ band gap. But the carrier drift length in most conjugated polymers and fullerenes, within which photon generated carriers can be collected by electrodes, is generally less than this thickness. Carrier drift length depends upon carrier mobility, carrier recombination lifetime, and built-in electric field. Thus, the low carrier drift length of conjugated polymers is caused by low carrier mobility and the low built-in electric field in the polymer layer. The electric field is a driving force for the photogenerated electrons and holes toward their respective electrodes and results from the work-function difference between the anode and the cathode.

In general, the present invention is directed to enhancing the built-in electric field of an OPV to increase the carrier drift length and reduce carrier recombination thereby increasing the short circuit current, the fill factor, and the open circuit voltage and ultimately the energy conversion efficiency of an OPV that comprises one or more aspects of the present invention. More specifically, the aforementioned enhancement in the built-in electric field is realized by including in the OPV a dipole region generally disposed between the organic active region and the cathode (a “cathode dipole region”), a dipole region generally disposed between the organic active region and the anode (an “anode dipole region”), or both a cathode dipole region and an anode dipole region in order to reduce carrier recombination and maximize the energy conversion efficiency. The electric field built into the OPV with one or more of these dipole regions has a relatively large polarization and produces a relatively large electric field compared to the electric field resulting from the electrode work function difference. This relatively large built-in electric field extends comparatively far into the active, semiconducting region of the OPV and significantly enhances exciton separation.

Thus, in accordance with the foregoing, the present invention is directed to an organic photovoltaic cell comprising: (a) a cathode; (b) an anode; (c) an organic active region for absorbing photons and generating excitons disposed between the cathode and the anode; and (d) (i) a cathode dipole region generally disposed between the organic active region and the cathode, wherein the cathode dipole region exhibits a positive charge near the organic active region, (ii) an anode dipole region generally disposed between the organic active region and the anode, wherein the anode dipole region exhibits a negative charge near the organic active region, or (iii) both (i) and (ii).

### A. Cathode

The cathode of the organic photovoltaic cell of the present invention may be configured (e.g., width, length, thickness, shape, etc.) in any appropriate manner. For example, an OPV cathode is typically planar with a thickness in the range of about 1 to about 200 nm and usually about 100 nm. Further, the cathode may be made of any appropriate material or combination of materials that in conjunction with the anode material(s) results in a difference in the work function between them to produce an electric field in the organic active region. The potential created by the different work functions helps to separate the excitons or bound electron-hole pairs by pulling electrons to the cathode and holes to the anode. For example, an OPV cathode may comprise magnesium, aluminum, calcium, lithium, sodium, potassium, strontium, cesium, barium, iron, cobalt, nickel, copper, silver, zinc, tin, samarium, ytterbium, chromium, gold, graphene, an alkali metal fluoride, an alkaline-earth metal fluoride, an alkali metal chloride, an alkaline-earth metal chloride, an alkali metal oxide, an alkaline-earth metal oxide, a metal carbonate, a metal acetate, or combinations thereof.

Results to date indicate that a particularly useful embodiment of the cathode comprises one or more of calcium, aluminum, magnesium, and lithium. For example, such a calcium-containing cathode may comprise a core that comprises calcium and a layer encapsulating the core (to the reactive nature of calcium) that comprises aluminum, magnesium, and/or lithium due. That said, in one or more embodiments of the present invention, calcium may be selected as the cathode material and the protection provided by other components of the PV cell eliminates the need for the aforementioned metallic encapsulating layer.

### B. Anode

The anode of the organic photovoltaic cell of the present invention may be configured (e.g., width, length, thickness, shape, etc.) in any appropriate manner. For example, an OPV anode is typically planar with a thickness of about 1 to about 200 nm (more typically around 100 nm). Further, the anode may be made of any appropriate material or combination of materials that in combination with the cathode results in a difference in the work function between them to produce an electric field in the organic active region. For example, an OPV anode may comprise indium-tin oxide (ITO), indium-zinc oxide, silver, gold, platinum, copper, chromium, indium oxide, zinc oxide, tin oxide, a polyaniline (PANI)-based conducting polymer, a 3,4-polyethylenedioxythiopene-polystyrenesultonate (PEDOT)-based conducting polymer, carbon nanotubes (CNT), graphite, graphene, graphene oxides, molybdenum oxide, tungsten oxide, vanadium oxide, silver oxide, aluminum oxide, or combinations thereof. Results to date indicate that a particularly useful embodiment of the anode comprises indium-tin oxide.

1. Substrate

Typically, the anode is supported by a transparent substrate such as glass or a flexible polymer such as polyethylene terephthalate (PET), polyethylene naphthalate (PEN), and poly(4,4′-oxydiphenylene-pyromellitimide) (KAPTON available from DuPont) that is from about 1 to about 5 mm thick. That said, however, OPV devices may be made with an “inverted” structure, wherein the cathode is supported by a substrate. Results to date suggest a thickness of about 1 mm provides a good compromise between the various relevant parameters such as strength, flexibility, and transmission. Specifically, the substrate is situated such that it is in contact with at least a portion of a surface of the anode, wherein said anode surface is that which is furthest from the cathode.

2. Smoothing Layer

The OPV of the present invention may further comprise a polymeric smoothing layer on at least a portion of a surface of the anode, wherein said surface is the one nearest or facing the cathode. Such a polymeric smoothing layer preferably comprises one or more materials that are generally considered to be hole conducting. Another function of this smoothing layer is to increase the work function of the electrodes to provide a higher built-in potential. For example, such a polymeric smoothing layer may comprise a mixture of poly(3,4-ethylenedioxythiophene) and poly(styrenesulfonate), which is often referred to as PEDOT:PSS.

3. Hole-Conducting, Electron-Blocking Layer

The OPV of the present invention may further comprises a hole-conducting, electron-blocking layer disposed generally between the anode and the active region. If present a smoothing layer is present, it is typically preferred for the hole-conducting, electron-blocking layer to be formed such that it is between the smoothing layer and the and the active region. An exemplary material for the hole-conducting, electron-blocking layer is N,N′-Bis-(3-methylphenyl)-N,N′-bis-(phenyl)-benzidine (TPD).

### C. Active Region

Disposed generally between the cathode and the anode is an organic active region for absorbing photons and generating excitons. The active region has a thickness that in the range of about 80 to about 1000 nm, depending upon the particular materials selected. Results to date indicate that a thickness that is within the range of about 80 to about 200 nm provides a good combination performance, ease of manufacturing, and cost.

Typically, an active region comprises electron donor material and an electron acceptor material, which have differences in electron affinity and ionization energy such that electrostatic forces are generated at the interface between the materials. Preferably, these materials are selected to make the differences large enough so the local electric fields are great enough to help break up generated excitons. As with the other components of the cell, the organic active region may be configured in any appropriate manner. For example, the organic active region may be configured as a “bilayer” organic active region in which the electron donor material constitutes an electron donor layer nearer the anode than the cathode and the electron acceptor material constitutes an electron acceptor layer nearer the cathode than the anode. Alternatively, the organic active region may be configured as a “heterojunction” active region in which the electron donor material and the electron acceptor material are mixed. Typically, the blend ration of the electron donor and the electron acceptor is within the range of about 1:20 to about 20:1 and preferably within the range of about 1:6 to about 6:1. The heterojunction is generally considered to be advantageous when the length scale of the blend is similar to the exciton diffusion length, which results in most of the excitons generated in either material to reach an interface where they can separate more efficiently. Heterojunction-type active regions include, for example, “highly-folded” configurations and “controlled-growth” configurations. The blended active region polymers may be deposited by any appropriate method such as spin-coating, spray coating, ink-jet printing, doctor-blade coating, dip coating, etc. Alternatively, the polymers may be mixed during the film formation process by, for example, spraying or thermal evaporation with two or more polymer sources.

1. Electron Donor Material

The electron donor material may be any appropriate material or combination of materials. For example, the electron donor material may be selected from the group consisting of a phthalocyanine complex, a porphyrin complex, a polythiophene (PT) and derivatives thereof, a polycarbazole and derivatives thereof, a poly(p-phenylene vinylene) (PPV) and derivatives thereof, a polyfluorene (PF) and derivatives thereof, a cyclopentadithiophene-based polymer, a benzodithiophene (BDT)-based polymer, their small molecules and monomers, and combinations thereof.

Polythiophenes and derivatives thereof and polycarbazoles and derivatives thereof are believed to be good choices for the electron donor material. More specifically, the following are believed to be particularly desirable electron donor materials: poly(3-hexylthiophene) (P3HT), poly(3-octylthiophene) (P3OT), poly(3-hexyloxythiophene) (P3DOT), poly(3-methylthiophene) (PMeT), poly(3-dodecylthiophene) (P3DDT), poly(3-dodecylthienylenevinylene) (PDDTV), poly(3,3 dialkylquarterthiophene) (PQT), poly-dioctyl-fluorene-co-bithiophene (F8T2), poly-(2,5,-bis(3-alkylthiophene-2-yl)thieno[3,2-b]thiophene) (PBTTT-C12), poly[2,7-(9,9′-dihexylfluorene)-alt-2,3-dimethyl-5,7-dithien-2-yl-2,1,3-benzothiadiazole] (PFDDTBT), poly{[2,7-(9,9-bis-(2-ethylhexyl)-fluorene)]-alt-[5,5-(4,7-di-20-thienyl-2,1,3-benzothiadiazole)]} (BisEH-PFDTBT), poly{[2,7-(9,9-bis-(3,7-dimethyl-octyl)-fluorene)]-alt-[5,5-(4,7-di-20-thienyl-2,1,3-benzothiadiazole)]} (BisDMO-PFDTBT), poly[N-9″-hepta-decanyl-2,7-carbazole-alt-5,5-(4′,7′-di-2-thienyl-2′,1′,3′-benzothiadiazole)] (PCDTBT), and combinations thereof.

2. Electron Acceptor

The electron acceptor material may be any appropriate material or combination of materials. For example, the electron acceptor material may be selected from the group consisting of a fullerene and derivatives thereof, a perylene derivative, a 2,7-dicyclohexyl benzo[lmn][3,8]phenanthroline derivative, a 1,4-diketo-3,6-dithienylpyrrolo[3,4-c]pyrrole (DPP) derivative, a tetracyanoquinodimethane (TCNQ) derivative, a poly(p-pyridyl vinylene) (PPyV) derivative, a 9,9′-bifluorenylidene (99BF) derivative, a benzothiadiazole (BT) derivative, and combinations thereof.

Results to date indicate that fullerenes and derivatives thereof to be good choices for the electron acceptor material. More specifically, the following are believed to be particularly desirable electron acceptor materials: [6,6]-phenyl C₆₁-butyric acid methyl ester (PCBM), [6,6]-phenyl C₆₁-butyric acid methyl ester (PC₇₀BM), [6,6]-(4-fluoro-phenyl)-C₆₁-butyric acid methyl ester (FPCBM), carbon 60 (C₆₀), carbon 70 (C₇₀), carbon nanotube (CNT), a carbon onion, and combinations thereof.

### D. Dipole Region(s)

As mentioned above, the OPV of the present invention comprises (i) a cathode dipole region generally disposed between the organic active region and the cathode, wherein the cathode dipole region exhibits a positive charge near the organic active region, (ii) an anode dipole region generally disposed between the organic active region and the anode, wherein the anode dipole region exhibits a negative charge near the organic active region, or (iii) both (i) and (ii). Said dipole region(s) may be formed according to any appropriate method for forming a region or layer comprising polar or charged materials or molecules that are aligned and fixed in position such that particular region has the appropriate charge near the active region. Such a dipole region typically has a thickness that is in the range of about 1 to about 20 nm but can be as thick as about 100 nm. In general, it is usually desirable to minimize the thickness of a dipole region in order to increase the efficiency of the cell. There are three general types of dipole regions disclosed herein: a dipole region comprising inorganic nanorods with a relatively high permanent dipole moment, a dipole region comprising ferroelectric polymers, and a dipole region comprising organic ions.

1. Nanorod-Type Dipole Regions

In this embodiment of an OPV of the present invention, the cathode dipole region comprises permanent dipole nanorods aligned and fixed in a cathode-dipole-region cross-linked matrix that comprises an electron transport material so that cathode dipole region exhibits a positive charge near the organic active region. Similarly, a nanorod-type anode dipole region comprises permanent dipole nanorods aligned and fixed in an anode-dipole-region cross-linked matrix that comprises a hole transport material so that the anode dipole region exhibits a negative charge near the organic active region.

a. Nanorods

The permanent dipole nanorods of the organic photovoltaic cell of the present invention may be configured (e.g., diameter and length) in any appropriate manner. For example, typical nanorods have a diameter in the range of about 1 to about 50 nm and a length in the range of about 2 to about 100 nm. Results to date indicate that the nanorods have a diameter that is in the range of about 5 to about 10 nm and a length that is in the range of about 10 to about 20 nm.

The permanent dipole nanorods may be comprised of any appropriate material or combination of materials. For example, the aligned permanent dipole nanorods may comprise CdSe, CdS, CdTe, ZnO, TiO₂, PbTe, PbS, Cu₂S, FeS₂, BaTiO₃, PbTiO₃, lead zirconate titanate (PZT) (Pb[ZrₓTi₁₋ₓ]O₃, wherein 0≦x≦1), lead lanthanum zirconate titanate (PLZT) (lanthanum-doped lead zirconate titanate), lead magnesium niobate (PMN), and combinations thereof. Results to date indicated that CdSe nanorods to be desirable.

b. Organic Matrix

The organic matrix may be of any appropriate material or combination of materials. As indicated above, the make-up of the cross-linked matrix depends on whether the dipole region is a cathode dipole region or an anode dipole region. Specifically, for the cathode dipole region the matrix comprises an electron transport material (e.g., having a hole mobility of at least about 10⁻³ cm²/V·s) whereas the matrix of an anode dipole region comprises a hole transport materials (e.g., an electron mobility of at least about 10⁻³ cm²/V·s). Examples of appropriate electron transport materials for the matrix include oxetane-functionalized oxadiazole, a fullerene derivative, and combinations thereof. Examples of appropriate hole transport materials for the matrix include a cross-linked functionalized triarylamine derivative. More specifically, desirable functionalized triarylamine derivatives include N,N′-Bis-(3-methylphenyl)-N,N′-bis-(phenyl)-benzidine (TPD)-[Si(OCH₃)₃]₂, TPD-[(CH₂)₆C₆H₁₁O]₂, oxetane-derivatized TPD, TPD-OCH₃, and combinations thereof.

These molecules can be cross-linked by heat treatment/UV light or through condensation. For example, TPD-[Si(OCH₃)₃]₂ readily undergoes hydrolysis and undergoes subsequent —OH+OH— condensation by thermal treatment to yield heavily cross-linked, glassy matrices. These materials can be applied on a variety of surfaces using self-assembly, spin-coating, spray coating, and ink-jet printing. The coated films are microstructurally well-defined, robust, conformal, electroactive, adherent, essentially pinhole free, and thermally stable. Hole transport materials such as these are known to promote in both small molecule and polymer OLEDs by increasing interface affinity while simultaneously reducing the hole injection barrier. Ultraviolet photoemission spectroscopy (UPS) results reveal that indium-tin oxide coated with such hole transport materials have a work function in the range of about 5.2 to about 5.3 eV, compared to about 4.7 eV for indium-tin oxide alone, which explains the enhanced hole injection from the anode to the active region layer. The higher work function thereby results in a higher open circuit voltage. Moreover, the hydrophobic nature of these materials can also moderate the surface energy mismatch at the interface between a hydrophilic oxide anode and hydrophobic buffer layer leading to improved physical integrity of the interface between an anode and the dipole region and improved thermal durability for the organic photovoltaic cell high OPV thermal durability, which is not known to be achievable with other anode functionalization structures, such as PEDOT. After cross-linking of TPD-[Si(OCH₃)₃]₂, no thermal transitions are observed by differential scanning calorimetry (DSC) in the 50-400° C. range, indicating cross-linked TPD is extremely thermally stable.

c. Formation of Nanorod Dipole Region(s)

A dipole region comprising permanent dipole nanorods may be formed by dispersing the nanorods in a solution comprising the organic matrix precursor and a solvent. Typically, the solvent is selected so that it is a polar solvent that is of a neutral or near neutral pH. The reason for this is that it will tend not to affect any of the polymers of the active region, which are dissolved in non-polar solvents. Further, because the pH is neutral or nearly so, anodes such as indium-tin oxide tend not to be etched in contrast to what happens with the strong acid solvents needed for PEDOT:PSS in contact with anodes of conventional OPVs.

Typically the ratio of nanorods to matrix precursor is within the range of about 1:20 to about 20:1 (by weight) and results to date indicate that a ratio within the range of about 1:2 to about 2:1 being preferred. As mentioned above, this mixture may be applied to surfaces by a variety of methods such as ink-jet printing. After depositing the mixture as desired, the solvent is evaporated and the matrix precursor is cured thereby cross-linking the matrix while the nanorods are aligned by application of an electric field of the desired strength. In general, it has been found that desirable results for aligning the nanorods are attained with an electric field in the range of about 0.1 to about 30 MV/m and typically at about 1 MV/m. It is to be noted that alternating current tends to be more efficient than direct current thereby allowing for less voltage to be used to obtain comparable results. Not only are the foregoing electric field strengths applicable for aligning permanent nanorods, they are appropriate for aligning the ferroelectric polymers and the ions in the other types of dipole regions described herein.

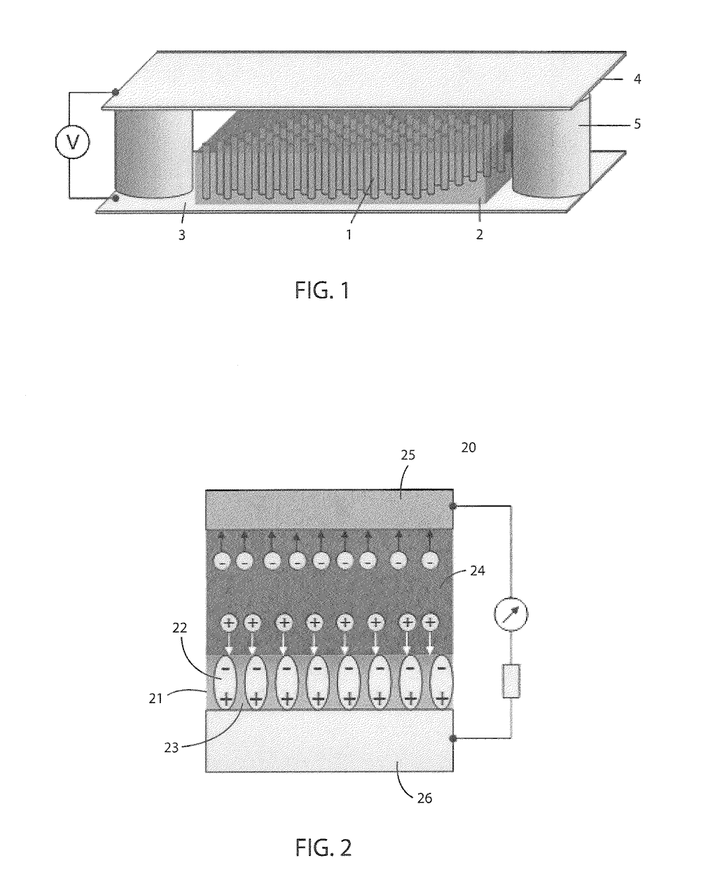

A set up for forming an anode dipole region comprising nanorods in a cross-linked matrix is depicted in FIG. 1. As is shown, the dipole region is formed by depositing the aforementioned mixture of nanorods 1 and matrix precursor and solvent (collectively 2) on an ITO glass 3. An electric field in accordance with the foregoing, is applied while the matrix precursor is cross-linked by application of voltage between an electrode 4 separated with spacers 5 above the ITO glass 3. After, aligning and fixing the permanent dipole nanorods within the cross-linked organic matrix, the remainder of the organic photovoltaic cell of the present invention may be formed. For example, referring to FIG. 2, in the OPV cell 20, which comprises an anode dipole region 21 that comprises the aligned and fixed permanent dipole rods 22 fixed in the cross-linked matrix 23 on the anode 26. The active region 24 is deposited on the anode dipole region 21 and the cathode 25 is deposited upon the active region. Further, as depicted, in use electrons are attracted to the cathode whereas the holes attracted to the negative charge of the dipole region near the active region and on toward the anode.

d. Benefits Realized with Nanorod Dipole Regions

Without being held to a particular theory, it is believed that the voltage loss in OPVs, especially bulk heterojunction OPVs, is the result of their field-driving nature and dark current in the diode. It is believed a stronger built-in electric field resulting from one or more dipole regions or layers is able to decrease such losses and result in an increased V_{oc}. More specifically, it is believed that the stronger built-in electric fields near the interface(s) between the active region and the dipole region(s) leads to a reduction in the saturated dark current injection component and, hence, to an increase of the V_{oc}. In certain embodiments of the present invention, a dipole region is able to increase the built-in electric field by up to a factor of ten. For example, the best previously known performance of a P3HT:PCBM PV cell is about 5 V/μm (1 V/0.2 μm; the built-in electric field was calculated according to the effective work-function difference of cathode and anode/thickness of active film. In contrast, the electric field generated by a dipole layer comprising permanent CdSe dipole nanorods, Eₘₐₓ, was determined to be 50 V/μm for a nanorod volume fraction of unity using the formula: E=4πσf/ε, wherein ε is the dielectric permittivity of the organic matrix and f is the volume fraction occupied by the dipole particle.

In addition, the leakage current can be reduced by selecting materials for a dipole region that are effective at electron blocking and hole transporting for an anode dipole region and hole blocking and electron transporting for a cathode dipole region. For example, both the organic matrix and nanorod materials may be selected to have good hole transport ability but poor electron transport ability.

It is also believed that the work function of the anode can be enhanced by the dipole layer due to formation of a better contact between the organic matrix of the dipole region and the organic active region with the reduced energy difference between the Highest Occupied Molecular Orbital (HOMO) of polymer(s) in the active region and the work function of the anode.

The I_{sc} is directly determined by external quantum efficiency, and the external quantum efficiency is the product of efficiencies in four steps of its operation: (1) light absorption by donor and acceptor molecules (η_{LA}); (2) exciton diffusion to donor/acceptor interface (η_{ED}); (3) charge transfer efficiency between donor and acceptor (η_{CT}); and (4) charge collection by electrode. In a polymer PV cell, the value of η_{LA}, η_{ED}, and η_{CT} can approach unity in many donor/acceptor systems with optimized morphology. Therefore, it is the carrier collection efficiency that determines the short circuit current for a selected polymer. A dipole layer can increase carrier extraction and, hence, increase I_{sc} because the enhanced electric field penetrating the active polymer film tends to reduce carrier recombination and increase carrier diffusion length, which can allow for a thicker active layer to enhance light absorption.

In the nanorod embodiment of the present invention, the I_{sc} can also be increased due to the fact that nanorods allow for the formation of a simple tandem cell allowing for absorption of both visible wavelengths by the organic materials of infrared wavelengths by the inorganic nanorods. For example, CdSe nanorods within the aforementioned size ranges have a low bandgap about 1.7-1.8 eV, which absorbs infrared light to about 720 nm, at which many organic semiconductors, like P3HT, have no response.

Further, it is believed that a dipole layer reduces or eliminates the energy barrier between the active region and anode thereby increasing the hole transfer rate from active layer to anode and reducing the hole accumulation at the anode side. This higher charge-transfer rate also leads to a lower charge-transfer resistance (or series resistance) at the polymer/anode interface and results in a higher fill factor.

2. Ferroelectric Polymer Dipole Regions

In this embodiment of an OPV of the present invention, the cathode dipole region comprises a cathode-dipole-region ferroelectric polymer, the molecules of which are aligned and fixed so that the cathode dipole region exhibits a positive charge near the organic active region. Similarly, the anode dipole region comprises an anode-dipole-region ferroelectric polymer, the molecules of which are aligned and fixed so that the anode dipole region exhibits a negative charge near the organic active region. Ferroelectric polymers are a group of crystalline polar polymers with net dipole moments that are also ferroelectric, meaning that they maintain a permanent electric polarization that can be reversed, or switched, in an external electric field, which allows for alignment to form macroscopic polarization. By including ultrathin ferroelectric polymer films in an OPV of the present invention, OPV cell may have local controllable electric-field enhancements. Further, the field of the dipole layer extends into the charge-generation active region thereby helping to separate excitons.

a. Ferroelectric Polymer

The cathode-dipole-region ferroelectric polymer and the anode-dipole-region ferroelectric polymer are independently selected from the group consisting of a vinylidene flouride-trifluoroethylene copolymer, vinylidenenitrile-trifluorethylene copolymer, cyanopolymers, vinylidene chloride-trifluoroethylene copolymers, and combinations thereof. Vinylidene fluoride-trifluroethylene copolymers P(VDF-TrFE) are an excellent choice for the ferroelectric polymer because they have a relatively high polarization, outstanding crystallinity, and enable fast switching. For the same reasons, cyanopolymers which have —C═N ligands in place of the fluorine —F ligands of VDF copolymers also make excellent ferroelectric polymers for the OPV cells of the present invention. Advantageously, using a ferroelectric polymer cathode region allows for a low work function without the use of a calcium such that the cathode may be free of calcium (e.g., consisting of aluminum), which can help extend the life of the OPV.

b. Formation of the Dipole Region

A ferroelectric ultrathin-film can be fabricated by a variety of conventional ultrathin-film casting techniques such as Langmuir-Blodgett deposition, spin coating and spray coating. In particular, using Langmuir-Blodgett deposition allows for the thickness of the dipole region to be accurately controlled by the number of deposited monolayers.

The dipole region may be configured in any appropriate manner. That said, the thickness of a dipole region comprising a ferroelectric polymer is preferably less than the tunneling length of a hole or electron as the case may be. In view of this, the thickness is typically within the range of about 0.5 nm to about 20 nm. Results to date indicate that a desirable thickness is within the range of about 1 to about 5 nm.

In certain embodiments of the ferroelectric polymer-type dipole region, a dipole region may comprise a continuous deposit. Specifically, a cathode dipole region may comprise a continuous deposit of the cathode-dipole-region ferroelectric polymer and an anode dipole region may comprise a continuous deposit of the anode-dipole-region ferroelectric polymer. Alternatively, one or both of the dipole regions may comprise a multiplicity of discontinuous deposits (“nanomesas”) of the cathode-dipole-region ferroelectric polymer or the anode-dipole-region ferroelectric polymer, as the case may be. In such a nanomesa embodiment, the nanomesas tend to have a circular cross-section, the diameter of which is typically in the range of about 10 to about 500 nm and preferably in the range of about 50 to about 130 nm. Adjacent nanomesas are typically spaced apart by a distance within the range of about 10 to 500 nm and preferably within the range of about 50 to about 130 nm. In general, as the thickness of the dipole region increases there is a tendency for the difference in the surface energy between the ferroelectric polymer and the polymers of the active region to form nanomesas. For example, Langmuir-Blodgett deposition of P(VDF-TrFE) on P3HT:PCBM resulted the formation of nanomesas with the third monolayer, whereas one and two deposited monolayers resulted in a continuous deposit.

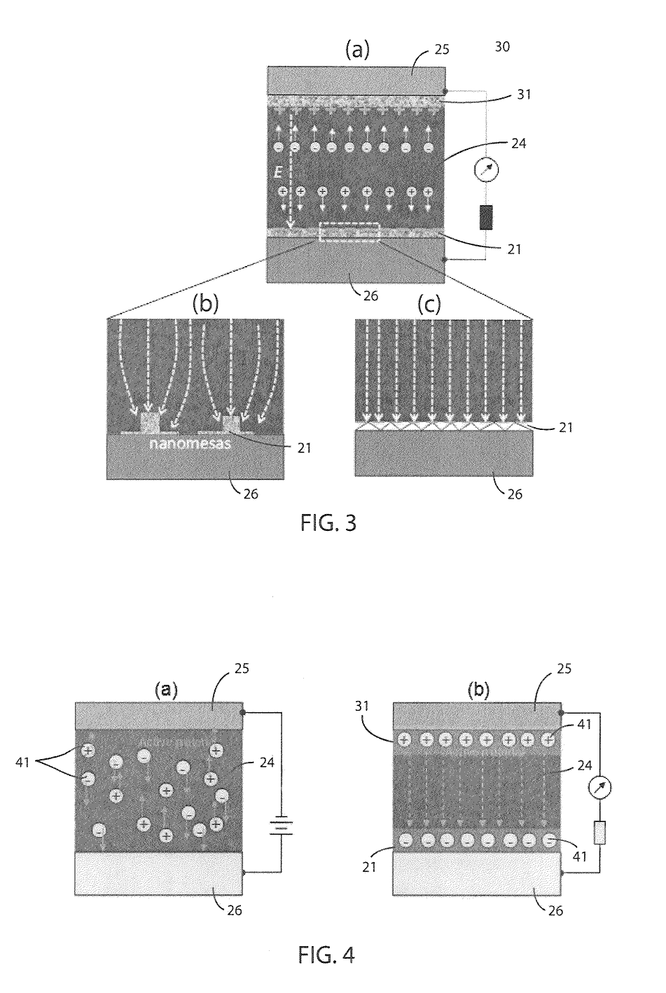

After depositing a ferroelectric polymer one an electrode, the active region may be deposited, followed by the other ferroelectric polymer, and the other electrode. The ferroelectric polymers of the two dipole regions are allowed to cure (for example by elevating the temperature of the ferroelectric polymers to within the range of about 110 to about 120° C.) while subject to an electric field as described above to align and fix the ferroelectric polymer molecules. After aligning and fixing the ferroelectric polymer of the dipole regions, an OPV of the present invention is formed. For example, referring to FIGS. 3(a), (b), and (c), the OPV cell 30 comprises an anode dipole region 21 that comprises an aligned and fixed ferroelectric polymer and a cathode dipole region 31 that also comprise an aligned and fixed ferroelectric polymer. The active region 24 is between the anode dipole region 21 and the cathode dipole region 31. The cathode 25 is adjacent the cathode region dipole 31 and the anode 26 is adjacent the anode dipole region 21. FIG. 3(b) depicts an anode dipole region 21 that comprises a multiplicity of discontinuous deposits (nanomesas) whereas FIG. 3(c) depicts an anode dipole region 21 that is substantially continuous. The nanomesas embodiment set forth in FIG. 3(b) exemplifies a meaning of the dipole region being “generally disposed between the organic active region” and its respective electrode. The dipole region, as a whole, is disposed between the organic active region and its respective electrode. But, as shown, there are discrete volumes of the polymer(s) of the active region that separate the nanomesas and extend to the electrodes or coatings thereon. Thus, at those locations within the dipole region, there is no dipole material. That said, the size and spacing of the nanomesas within the dipole region is such that it is believed that their collective effective is that of a single dipole region extending over the region in which the nanomesas are located.

c. Benefits Realized with Ferroelectric Polymer Dipole Regions

The carrier collection efficiency determines the short circuit current I_{sc} for a selected polymer. The following factors will contribute to the increase of I_{sc} from the devices. The proposed ferroelectric layer can bring additional electric field into the polymer film other than that from the two different electrodes, which increases carrier collection efficiency and hence increase I_{sc}. There are two main channels for the loss of photoexcited carriers: loss by high density carrier traps, dead end in the polymer blends, and the recombination of electrons and holes. The built in electric field in regular bulk heterojunction (BHJ) OPVs is not strong enough to pull all of the carriers out of most semiconducting polymer films. For the best reported performing P3HT:PCBM PV cells, the calculated built-in electric field according to effective work-function difference of cathode and anode divided by thickness of the active region is about 1 V/0.2 μm or 5 V/μm. The built-in electric field introduced by the P(VDF-TrFE) dipole layer can exceed 1000 V/μm, considering a remanent polarization of 0.1 C/m² as has been measured directly using Stark spectroscopy. This enhanced electric field readily penetrates the active polymer film, since both layers have low permittivity, and can therefore reduce carrier recombination and increase carrier drift length, also allowing a thicker polymer layer to absorb more sun light. In addition, the strong electric field is expected to accelerate the exciton splitting and increase its efficiency, which has been found to be a necessary with fullerenes, which are widely used in high efficiency OPV devices as the acceptor.

The dipole layer helps to separate excitons and reduce energy loss crossing the barrier. The variation in charge-collection rate is due to the variation of the energy step at the interface. The strong electric field reduces or eliminates this energy barrier and hence increases hole transfer rate from active layer to anode, and reduces hole accumulation at anode side. This higher charge-transfer rate also leads to a lower charge-transfer resistance (or series resistance) at polymer/anode interface, and results in a higher fill factor.

The voltage loss in OPVs, especially bulk heterojunction OPVs, was believed to result from its field-driving nature and dark current in the diode. In this invention, the ferroelectric layer has the advantage of increasing the open-circuit voltage V_{oc} by suppressing these losses. It is believed that this is accomplished, at least in part, by the strong built-in electric field near the surface, which leads to a reduction of the saturated dark current injection component, and hence to the increase of V_{oc}. A second mechanism believed to increase the V_{oc} is that the strong dipole moment in the ferroelectric material changes the work function of electrode. The open circuit voltage in many cases has been found to increase with a low work function cathode or/and a high work function anode. The work function of a modified anode by a poled (i.e., aligned and fixed) ferroelectric polymer can be studied by UPS measurement or/and by measuring the dark current of device. Each method has its own advantages: UPS can directly measure the work function a surface, and current fitting methods can tell the real energy barrier at the interface.

3. Organic Salt Dipole Regions

In this embodiment of an OPV of the present invention, the cathode dipole region comprises cations dispersed within a cathode-dipole-region polymer, wherein the cations are sufficiently large so as to be essentially immobile at temperatures below the glass transition temperature of the cathode-dipole-region polymer so that the cathode dipole region exhibits a positive charge near the organic active region. Similarly, the anode dipole region comprises anions dispersed within an anode-dipole-region polymer, wherein the anions are sufficiently large so as to be essentially immobile at temperatures below the glass transition temperature of the anode-dipole-region polymer so that the anode dipole region exhibits a negative charge near the organic active region.

a. Ions

The selection of the ions tends to be quite important in the fabrication of high-performance OPVs of the present invention. Preferably, the organic salts, which are the source of the aforementioned ions, have (a) a good solubility in common organic solvents, such as toluene, hexane, and acetonitrile, which tends to simplify fabrication (b) a relatively high decomposition temperature (e.g., above 200° C.), which allows the OPV to have high performance at typical operation temperatures, and (c) a melting temperature that is within the range of about 50 to about 90° C., which also tends to simplify fabrication by allowing the dipole regions to be formed at or near room temperature. Examples of appropriate anions include carboxylate anions, sulfonate anions, methanides (R₃C—), amides (R₂N—), polycyano anions, phenolate anions, organometallic anions, cyclopentadienide anions, and combinations thereof. Examples of appropriate cations include bis(ethylenedithio)tetraselenafulvalene, bis(ethylenedioxo)tetrathiafulvalene, tetrathiafulvalene, tetramethyltetrathiafulvalene, tetramethyltetraselenafulvalene, tetrathiafulvalene, and combinations thereof.

b. Formation of the Dipole Region

The salt(s) comprising the ions are blended and dissolved into the polymer(s) used to form the active region. Typically, the amount of organic salt(s) used to form the dipole regions is in the range of about 0.001 to about 10% by weight of the polymers used to form the active region. The fabrication of an OPV according to this embodiment is essentially identical to that for fabricating a conventional OPV but because the ions are mobile in the solid polymers used to also form the active region at elevated temperatures they can be moved upon application of an electric field. As illustrated in FIG. 4(a), an initial forward voltage (electric field) is applied to move the ions 41 to the vicinity of the electrodes while the polymers are at an elevated temperature that is above the melting point of the ions and the glass transition temperature of the polymer(s) such that the polymers serve as the solvent for the organic salts. For example, the temperature is typically elevated to within the range of about 50 to about 250° C. After the ions accumulate near their respective electrode, the temperature of the polymers is reduced to fix the ions in place because the ion diffusivity at room temperature are orders of magnitude lower than at the elevated temperature. Upon being fixed the dipole regions comprising the ions are formed in the OPV as depicted in FIG. 4(b).

As indicated above, the salt(s) are dissociated in polymers used to also form the active region. Thus, when fixed, the dipole region in addition to the ions comprise the same polymer(s) that are in the adjacent organic active region adjacent. Thus, the cations of the cathode dipole region are in a cathode-dipole region polymer that is the same as that of the organic active region adjacent to the cathode dipole region. Likewise, the anions of the anode dipole region are in an anode-dipole-region polymer that is the same as that of the organic active region adjacent to the anode dipole region. Thus, for a bilayer active region the cathode dipole region comprises an electron acceptor material and the anode dipole region comprises an electron donor material. For a heterojunction-type active region, in particular a highly-folded heterojunction-type of active region, the cathode dipole region and the anode dipole region each comprise both an electron acceptor material and an electron donor material.

c. Relationship of V_{oc} and the Built-In Potential

In an inorganic p-i-n solar cell, the built-in potential is generally recognized as the ultimate limit to V_{oc}. An OPV, however, is more complicated, because there is both an internal p-n junction between the donor and acceptor and an external electrical field. There is still no conclusive study on the relationship of V_{oc} and the built-in potential (V_{bi}) of OPVs, especially in bulk heterojunction OPV devices. The enhanced built-in electric fields formed included one or more dipole regions open the possibility for investigating the relationship between the V_{oc} and V_{bi}. A controllable built-in electrical field can easily be achieved by tuning the concentration of organic salts in the polymer blend. The maximum V_{bi} might be much higher than the work function difference between the two electrodes.

4. Combinations of Dipole Regions Types

A single OPV cell may comprise combinations of dipole layer types such as a nanorod-type anode dipole region with a ferroelectric polymer-type cathode region.

### EXAMPLES

### Example 1

### OPV with a Nanorod Anode Dipole Region

The patterned ITO-coated glass substrates were cleaned by successive ultrasonic treatment in detergent, acetone, and isopropyl alcohol. A chloroform solution of CdSe nanorods (1 wt %) and TPD-[Si(OCH₃)₃]₂ (1 wt %) was prepared and used to form a mixed CdSe:TPD-[Si(OCH₃)₃]₂ film on a cleaned ITO glass by spin coating at 800 rpm. Then an electric field E (1 MV/m) was quickly applied while the chloroform evaporated over the period of about 5 hours. This electric field was achieved by locating a gold-coated glass slide above the substrate with a distance of 300 μm with a Teflon spacer and applying a 300 V potential across the ITO and gold layer, as shown schematically in FIG. 1. Then, the perpendicularly aligned nanorod were fixed in position by crosslinking the TPD-[Si(OCH₃)₃]₂ at a temperature of about 100° C. for about 30 minutes. For the active layer, P3HT was first dissolved in 1,2-dichlorobenzene (DCB) to make 30 mg/ml solution, followed by blending with PCBM at a ratio of 1:1 by weight. The blend was stirred for about 14 hours at 40° C. in a nitrogen-filled glove box. The active layer was obtained by spin-coating the P3HT:PCBM (1:1 wt %, 30 mg/ml) at 800 r.p.m. for 20 seconds, and the thickness of the P3HT:PCBM film was approximately 150 nm. The Al cathode was evaporated through a shadow mask with an active area of approximately 10 mm².

### Example 2

### OPV with Ferroelectric Polymer Dipole Regions

A conventional OPV without dipole regions comprising an indium-tin oxide anode on a glass substrate, a PEDOT:PSS smoothing layer on the ITO, and active region comprising P3HT:PCBM; and aluminum cathode was formed. An identical OPV except for having a P(VDF-TrFE) containing cathode dipole region between the cathode and the active region was also formed.

For the device fabrication, PEDOT:PSS was first spin-cast onto a cleaned ITO/glass substrate at a spin speed of 3,500 r.p.m. to form a film with a thickness of approximately 30 nm. The spun PEDOT:PSS was then baked at about 120° C. for about 20 minutes before spin-casting the active region polymer film. The active region layer was obtained by spin-coating the P3HT:PCBM (1:1 wt %, 30 mg/ml) at 800 r.p.m. for 20 seconds to form a P3HT:PCBM film having a thickness that was approximately 150 nm. For the deposition of FE LB films, the random copolymer P(VDF-TrFE), containing 70% vinylidene fluoride and 30% trifluoroethylene, was dissolved in dimethyl sulphoxide with a concentration of 0.05% by weight. The polymer was dispersed on the surface of ultrapure (18 MΩcm) water and slowly compressed to a surface pressure of 5 mN/m at room temperature in air. Then the LB layer was transferred to a glass/ITO substrate covered with P3HT:PCBM film. The P(VDF-TrFE) films were deposited 1ML at a time by horizontal dipping. The samples were annealed at 135° C. in N₂ for half an hour to improve the crystallinity of the P(VDF-TrFE).

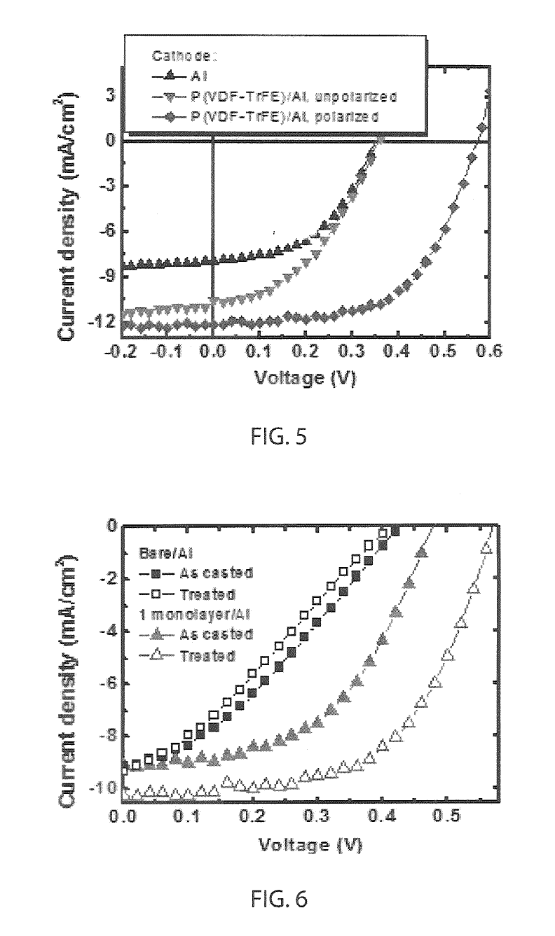

As is shown in FIG. 5, the insertion of a monolayer of P(VDF-TrFE) resulted in a small increase in the short-circuit current I_{sc}, probably due to the dielectric properties and partial polarization of P(VDF-TrFE). After polarizing by a −15 V reverse bias, both V_{oc} and I_{sc} increased by more than 25% over the control device, leading to an increase of efficiency from 1.6% to 4.2%. This level of efficiency is among the highest for P3HT:PCBM based devices with an aluminum cathode. Referring to FIG. 6, the effect on the efficiency by the dipole region can take into account the movement of ions in the various polymers in the cell by comparing OPVs comprising as cast polymers and heat treated at about 120° C. for about 15 seconds while under a −15 V electric field.

Testing different aligning (poling) procedures showed the benefits of aligning (poling) a ferroelectric polymer at an elevated temperature. Specifically, performing the poling at room temperature required about 50 minutes and increased the open circuit voltage from 0.48 V to 0.53 V whereas to about 120° C. the poling only required about 15 seconds and produced a higher open circuit voltage of 0.57 V.

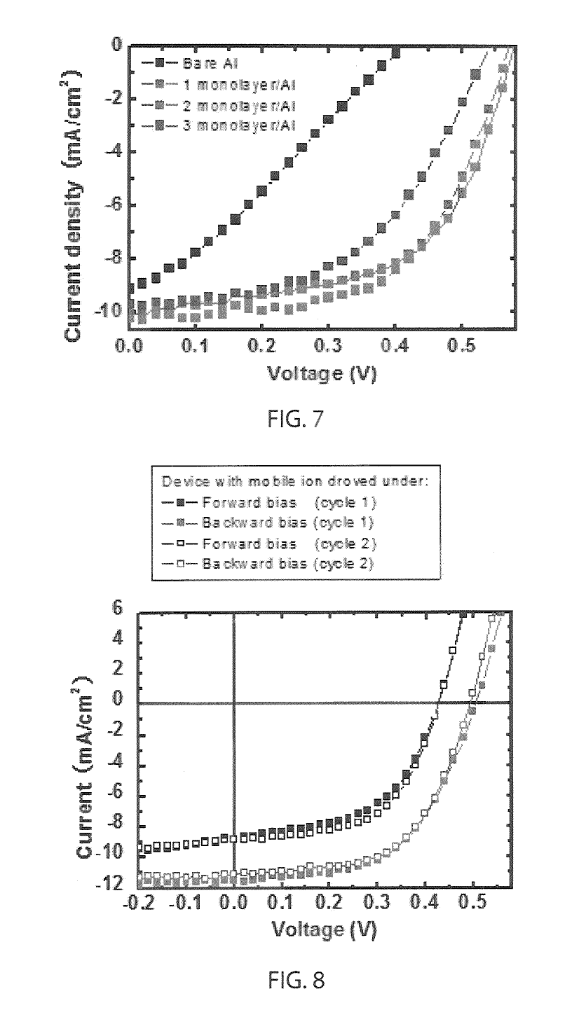

The effects of differing numbers of ferroelectric polymer monolayers on the performance of an OPV was also investigated and set forth in FIG. 7 and Table 1.

TABLE 1

| | J_{SC} | V_{OC} | PCE | |
|---|---|---|---|---|
| Cathode | (mA/cm²) | (V) | (%) | FF |
| Bare Al | 9.16 | 0.411 | 1.09 | 0.29 |
| 1 monolayer/Al | 10.25 | 0.570 | 3.39 | 0.58 |
| 2 monolayer/Al | 10.00 | 0.575 | 3.33 | 0.58 |
| 3 monolayer/Al | 9.72 | 0.537 | 2.65 | 0.51 |

One or two monolayers seemed to provide the optimal combination of properties for this device whereas increasing to three monolayers resulted a slightly reduced efficiency, although it is still much higher than the device without any ferroelectric layer. This can be well understood by the low conductivity of P(VDF-TrFE).

A review of the morphology of the different ferroelectric films also showed a correlation between morphology and device performance. The results of the morphology study are set forth in Table 2, which summarized the roughness of 0-3 monolayers of P(VDF-TrFE) on P3HT:PCBM, before and after annealing.

TABLE 2

| ITO/PEDOT/ | | |
|---|---|---|
| Polymer/ . . . | RMS | Ra |
| 0 | 1.724 | 1.379 |
| 0 (heated) | 1.542 | 1.212 |
| 1 ML | 1.14 | 0.918 |
| 1 ML (heated) | 1.16 | 0.917 |
| 2 ML | 1.248 | 1.001 |
| 2 ML (heated) | 0.982 | 0.782 |
| 3 ML | 0.790 | 0.651 |
| 3 ML (heated) | 3.587 | 2.798 |

The results set forth in Table 2 show that coating of ferroelectric polymer can make the film smoother. After annealing, the films of 1 and 2 monolayers of P(VDF-TrFE) become even more smoother, which may be the result of smoothing of P3HT:PCBM active region. Nevertheless, it is shown that 3 monolayers of the P(VDF-TrFE) ferroelectric polymer tended to form many nanomesas. The thickness of the nanomesa was around 10 nm making it more difficult for the tunneling of electrons through this layer, which explains the reduced voltage and current output.

### Example 3

### OPV with Organic Salt Dipole Regions

An OPV comprising an indium-tin oxide anode on a glass substrate, a PEDOT:PSS smoothing layer on the ITO, and active region comprising P3HT:PCBM; and aluminum cathode was formed. An amount of methyltrioctylammonium trifluoromethanesulfonate (MATS) organic salt in the range of about 2 to about 15% by weight of the polymers was mixed into said polymers.

The devices were fabricated on patterned ITO-coated glass substrates, which has been cleaned by successive ultrasonic treatment in detergent, acetone, and isopropyl alcohol. The ITO glass is then subjected to UV-ozone treatment for about 10 minutes. A thin layer of PEDOT:PSS film was spin-cast onto the ITO glass substrate with a spin speed of 3500 rpm for 1 minute and then baked at about 120° C. for about 20 minutes. The polymer layers were then spin-cast from the solution containing a 1:50-1:20 weight ratio of MATS and P3HT:PCBM (1:1 by weight) in DCB (spin speed of 800 rpm) for 20 seconds in the nitrogen glove-box. The Al cathode was evaporated through a shadow mask with an active area of approximately 10 mm². When the devices were heated to about 100° C. under 10 V forward bias, the movement of the ions in the polymers was observed. As shown in FIG. 8, the V_{oc} and I_{sc} can be significantly influenced by the direction of the electric field. When the device was subject to +1.5 V or −15 V alternately at a temperature of 120° C., the V_{oc} switched between 0.427 V and 0.500 V alternately at room temperature, meanwhile the I_{sc} switched between 8.85 mA/cm² and 11.2 mA/cm² alternately. The efficiency increased up to 3.2% when the cations and anion were frozen to form the cathode dipole region and the anode dipole region, which demonstrates the controllable strong built-in electrical field that can be attained with the present invention.

What is claimed is:

1. An organic photovoltaic cell comprising:
(a) a cathode;
(b) an anode;
(c) an organic active region for absorbing photons and generating excitons disposed between the cathode and the anode; and
(d) (i) a cathode dipole region generally disposed between the organic active region and the cathode, wherein the cathode dipole region exhibits a positive charge near the organic active region;
(ii) an anode dipole region generally disposed between the organic active region and the anode, wherein the anode dipole region exhibits a negative charge near the organic active region; or
(iii) both (i) and (ii).

2. The organic photovoltaic cell of claim 1, wherein:
the cathode comprises magnesium, aluminum, calcium, lithium, sodium, potassium, strontium, cesium, barium, iron, cobalt, nickel, copper, silver, zinc, tin, samarium, ytterbium, chromium, gold, graphene, an alkali metal fluoride, an alkaline-earth metal fluoride, an alkali metal chloride, an alkaline-earth metal chloride, an alkali metal oxide, an alkaline-earth metal oxide, a metal carbonate, a metal acetate, or combinations thereof;
the anode comprises indium-tin oxide, indium-zinc oxide, silver, gold, platinum, copper, chromium, indium oxide, zinc oxide, tin oxide, a polyaniline-based conducting polymer, a 3,4-polyethylenedioxythiopene-polystyrenesultonate-based conducting polymer, carbon nanotubes, graphite, graphene, graphene oxides, molybdenum oxide, tungsten oxide, vanadium oxide, silver oxide, aluminum oxide, or combinations thereof; and
the organic active region comprises:
(i) an electron donor material that is selected from the group consisting of a phthalocyanine complex, a porphyrin complex, a polythiophene and derivatives thereof, a polycarbazole and derivatives thereof, a poly(p-phenylene vinylene) and derivatives thereof, a polyfluorene and derivatives thereof, a cyclopentadithiophene-based polymer, a benzodithiophene-based polymer, their small molecule and monomers, and combinations thereof; and
(ii) an electron acceptor material that is selected from the group consisting of a fullerene derivative, a perylene derivative, a 2,7-dicyclohexyl benzo[lmn][3,8]phenanthroline derivative, a 1,4-diketo-3,6-dithienylpyrrolo[3,4-c]pyrrole derivative, a tetracyanoquinodimethane derivative, a poly(p-pyridyl vinylene) derivative, a 9,9′-bifluorenylidene derivative, a benzothiadiazole derivative, and combinations thereof.

3. The organic cell photovoltaic cell of claim 2, wherein:
the electron donor material is selected from the group consisting of poly(3-hexylthiophene), poly(3-octylthiophene), poly(3-hexyloxythiophene), poly(3-methylthiophene), poly(3-dodecylthiophene), poly(3-dodecylthienylenevinylene), poly(3,3 dialkylquarterthiophene), poly-dioctyl-fluorene-co-bithiophene, poly-(2,5,-bis(3-alkylthiophene-2-yl)thieno[3,2-b]thiophene), poly[2,7-(9,9′-dihexylfluorene)-alt-2,3-dimethyl-5,7-dithien-2-yl-2,1,3-benzothiadiazole], poly{[2,7-(9,9-bis-(2-ethylhexyl)-fluorene)]-alt-[5,5-(4,7-di-20-thienyl-2,1,3-benzothiadiazole)]}, poly{(2,7-(9,9-bis-(3,7-dimethyl-octyl)-fluorene)]-alt-[5,5-(4,7-di-20-thienyl-2,1,3-benzothiadiazole)]}, poly[N-9″-hepta-decanyl-2,7-carbazole-alt-5,5-(4′,7′-di-2-thienyl-2′,1′,3′-benzothiadiazole)], and combinations thereof; and
the electron acceptor material is selected from the group consisting of [6,6]-phenyl C₆₁-butyric acid methyl ester, [6,6]-phenyl C₆₁-butyric acid methyl ester, [6,6]-(4-fluoro-phenyl)-C₆₁-butyric acid methyl ester, carbon 60, carbon 70, carbon nanotube, a carbon onion, and combinations thereof.

4. The organic photovoltaic cell of claim 1, wherein the organic active region is a bilayer active region in which the electron donor material constitutes an electron donor layer nearer the anode than the cathode and the electron acceptor material constitutes an electron acceptor layer nearer the cathode than the anode.

5. The organic photovoltaic cell of claim 1, wherein the organic active region is a heterojunction active region in which the electron donor material and the electron acceptor material are mixed.

6. The organic photovoltaic cell of claim 1, wherein:
the cathode dipole region comprises permanent dipole nanorods aligned and fixed in a cathode-dipole-region cross-linked matrix that comprises an electron transport material so that cathode dipole region exhibits a positive charge near the organic active region; and
the anode dipole region comprises permanent dipole nanorods aligned and fixed in an anode-dipole-region cross-linked matrix that comprises a hole transport material so that the anode dipole region exhibits a negative charge near the organic active region.

7. The organic photovoltaic cell of claim 6, wherein the cathode comprises a core that comprises calcium and a layer encapsulating the core that comprises aluminum, magnesium, lithium, or a combination thereof.

8. The organic photovoltaic cell of claim 6, wherein:
the aligned permanent dipole nanorods comprise CdSe, CdS, CdTe, ZnO, TiO₂, PbTe, PbS, Cu₂S, FeS₂, BaTiO₃, PbTiO₃, lead zirconate titanate, lead lanthanum zirconate titanate, lead magnesium niobate, and combinations thereof;
the hole transport material comprises a cross-linked functionalized triarylamine derivative; and
the electron transport material comprises an oxetane-functionalized oxadiazole, a fullerene derivative, and combinations thereof.

9. The organic photovoltaic cell of claim 8, wherein the functionalized triarylamine derivative is selected from the group consisting of TPD-[Si(OCH₃)₃]₂, TPD-[(CH₂)₆C₆H₁₁O]₂, oxetane-derivatized TPD, TPD-OCH₃, and combinations thereof.

10. The organic photovoltaic cell of claim 1 further comprising a transparent substrate that is in contact with at least a portion of a surface of one of the electrodes, wherein said surface is furthest from the other electrode.

11. The organic photovoltaic cell of claim 1 further comprising a polymeric smoothing layer on at least a portion of a surface of the anode, wherein said surface is the one nearest the cathode, and said polymeric smoothing layer is hole conducting.

12. The organic photovoltaic cell of claim 11, wherein the polymeric smoothing layer comprises a poly(3,4-ethylenedioxythiophene) and poly(styrenesulfonate).

13. The organic photovoltaic cell of claim 1, wherein:
the cathode dipole region comprises a cathode-dipole-region ferroelectric polymer, the molecules of which are aligned and fixed so that cathode dipole region exhibits a positive charge near the organic active region;
the anode dipole region comprises an anode-dipole-region ferroelectric polymer, the molecules of which are aligned and fixed so that the anode dipole region exhibits a negative charge near the organic active region.

14. The organic photovoltaic cell of claim 13, wherein the cathode-dipole-region ferroelectric polymer and the anode-dipole-region ferroelectric polymer are independently selected from the group consisting of a vinylidene flouride-trifluoroethylene copolymer, vinylidenenitrile-trifluorethylene copolymer, cyanopolymers, vinylidene chloride-trifluoroethylene copolymers, and combinations thereof.

15. The organic photovoltaic cell of claim 13, wherein:
the cathode dipole region comprises a continuous deposit of the cathode-dipole-region ferroelectric polymer; and
the anode dipole region comprises a continuous deposit of the anode-dipole-region ferroelectric polymer.

16. The organic photovoltaic cell of claim 15, wherein:
the continuous deposit of the cathode-dipole-region ferroelectric polymer comprises one, two, or three monolayers of the cathode-dipole-region ferroelectric polymer; and
the continuous deposit of the anode-dipole-region ferroelectric polymer comprises one, two, or three monolayers of the anode-dipole-region ferroelectric polymer.

17. The organic photovoltaic cell of claim 13, wherein the cathode consists of aluminum.

18. The organic photovoltaic cell of claim 13, wherein:
the cathode dipole region comprises a multiplicity of discontinuous deposits of the cathode-dipole-region ferroelectric polymer; and
the anode dipole region comprises a multiplicity of discontinuous deposits of the anode-dipole-region ferroelectric polymer.

19. The organic photovoltaic cell of claim 18, wherein adjacent discontinuous deposits are spaced apart by about 0.5 nm to about 20 nm.

20. The organic photovoltaic cell of claim 1, wherein:
the cathode dipole region comprises cations dispersed within a cathode-dipole-region polymer, wherein the cations are sufficiently large so as to be essentially immobile at temperatures below the glass transition temperature of the cathode-dipole-region polymer so that the cathode dipole region exhibits a positive charge near the organic active region;
the anode dipole region comprises anions dispersed within an anode-dipole-region polymer, wherein the anions are sufficiently large so as to be essentially immobile at temperatures below the glass transition temperature of the anode-dipole-region polymer so that the anode dipole region exhibits a negative charge near the organic active region.

21. The organic photovoltaic cell of claim 20, wherein the anions are selected from the group consisting of carboxylate anions, sulfonate anions, methanides, amides, polycyano anions, phenolate anions, organometallic anions, cyclopentadienide anions, and combinations thereof; and the cations are selected from the group consisting of bis(ethylenedithio)tetraselenafulvalene, bis(ethylenedioxo)tetrathiafulvalene, tetrathiafulvalene, tetramethyltetrathiafulvalene, tetramethyltetraselenafulvalene, tetrathiafulvalene, and combinations thereof.

22. The organic photovoltaic cell of claim 20, wherein:
the cathode-dipole-region polymer is the same as that of the organic active region adjacent to the cathode dipole region; and
the anode-dipole-region polymer is the same as that of the organic active region adjacent to the anode dipole region.

23. The organic photovoltaic cell of claim 22, wherein the organic active region is a heterojunction active region that comprises an electron donor component and an electron acceptor component.

24. An organic photovoltaic cell comprising:
(a) a cathode;
(b) an anode;
(c) a heterogenic organic active region disposed between the cathode and the anode that comprises a mixture of an electron acceptor material and an electron donor; and
(d) an anode dipole region generally disposed between the organic active region and the anode that comprises permanent dipole nanorods aligned and fixed in an anode-dipole-region cross-linked matrix that comprises a hole transport material so that the anode dipole region exhibits a negative charge near the organic active region.

25. An organic photovoltaic cell comprising:
(a) a cathode;
(b) an anode;
(c) a heterogenic organic active region disposed between the cathode and the anode that comprises a mixture of an electron acceptor material and an electron donor;
(d) a cathode dipole region generally disposed between the organic active region and the cathode, wherein cathode dipole region comprises a cathode-dipole-region ferroelectric polymer the molecules of which are aligned and fixed so that cathode dipole region exhibits a positive charge near the organic active region; and
(e) an anode dipole region generally disposed between the organic active region and the anode, wherein the anode dipole region comprises an anode-dipole-region ferroelectric polymer the molecules of which are aligned and fixed so that the anode dipole region exhibits a negative charge near the organic active region.

26. An organic photovoltaic cell comprising:
(a) a cathode;
(b) an anode;
(c) a heterogenic organic active region disposed between the cathode and the anode that comprises a mixture of an electron acceptor material and an electron donor;
(d) a cathode dipole region generally disposed between the organic active region and the cathode, wherein cathode dipole region comprises cations dispersed within a cathode-dipole-region polymer, wherein the cations are sufficiently large so as to be essentially immobile at temperatures below the glass transition temperature of the cathode-dipole-region polymer so that cathode dipole region exhibits a positive charge near the organic active region; and
(e) an anode dipole region generally disposed between the organic active region and the anode, wherein the anode dipole region comprises anions dispersed within an anode-dipole-region polymer, wherein the anions are sufficiently large so as to be essentially immobile at temperatures below the glass transition temperature of the anode-dipole-region polymer so that the anode dipole region exhibits a negative charge near the organic active region.

27. A process of making an organic photovoltaic cell that comprises a cathode; an anode; an organic active region for absorbing photons and generating excitons disposed between the cathode and the anode; and a cathode dipole region generally disposed between the organic active region and the cathode, wherein the cathode dipole region exhibits a positive charge near the organic active region or an anode dipole region generally disposed between the organic active region and the anode, wherein the anode dipole region exhibits a negative charge near the organic active region, or both the cathode dipole region and the anode dipole region; the process comprising forming the dipole region(s) by delivering permanent dipoles, applying an electric field to the permanent dipoles to align the permanent dipoles, and fixing the position of the aligned permanent dipoles.

28. The process of claim 27, wherein:
the permanent dipoles are permanent dipole rods;
the permanent dipole rods are delivered in a cross-linkable liquid, wherein the cross-linkable liquid comprises an electron transport material in the case of the cathode dipole region and a hole transport material in the case of the anode dipole region; and
the aligned permanent dipole rods are fixed in position by cross-linking the cross-linkable liquid to form a cross-linked matrix.

29. The process of claim 28, wherein:
the permanent dipole nanorods comprise CdSe, CdS, CdTe, ZnO, TiO₂, PbTe, PbS, Cu₂S, FeS₂, BaTiO₃, PbTiO₃, lead zirconate titanate, lead lanthanum zirconate titanate, lead magnesium niobate, and combinations thereof;
the hole transport material comprises a cross-linked functionalized triarylamine derivative; and
the electron transport material comprises an oxetane-functionalized oxadiazole, a fullerene derivative, and combinations thereof.

30. The process of claim 27, wherein:
the permanent dipoles are a molecules of a ferroelectric polymer;
the molecules are delivered in the uncured form of the ferroelectric polymer; and
the aligned permanent dipoles are fixed in position by curing the ferroelectric polymer.

31. The process of claim 30, wherein the cathode dipole region ferroelectric polymer and the anode dipole region ferroelectric polymer are independently selected from the group consisting of a vinylidene flouride-trifluoroethylene copolymer, vinylidenenitrile-trifluorethylene copolymer, cyanopolymers, vinylidene chloride-trifluoroethylene copolymers, and combinations thereof.

32. The process of claim 30, wherein the uncured ferroelectric polymer is delivered in the form of one, two, or three monolayers, and the dipole region(s) comprise a continuous deposit of the ferroelectric polymer.

33. The process of claim 30, wherein the uncured ferroelectric polymer is delivered to a thickness sufficient for the dipole region(s) to comprise a multiplicity of discontinuous deposits of the ferroelectric polymer.

34. The process of claim 27, wherein:
the permanent dipoles are ions, which are dispersed within a polymer that is the same as that of the organic active region adjacent to the dipole region(s), wherein the ions are sufficiently large so as to be essentially immobile at temperatures below the glass transition temperature of the polymer, and wherein the ions are cations in the case of the cathode dipole region and anions in the case of the anode dipole region;
the ions are delivered and aligned by heating the polymer to a temperature at which the ions are mobile and applying the electric field to drive the ions to their respective dipole regions; and
the ions are fixed in position by decreasing the temperature of the polymer to a temperature at which the ions are essentially immobile.

35. The process of claim 34, wherein:
the anions are selected from the group consisting of carboxylate anions, sulfonate anions, methanides, amides, polycyano anions, phenolate anions, organometallic anions, cyclopentadienide anions, and combinations thereof; and
the cations are selected from the group consisting of bis(ethylenedithio)tetraselenafulvalene, bis(ethylenedioxo)tetrathiafulvalene, tetrathiafulvalene, tetramethyltetrathiafulvalene, tetramethyltetraselenafulvalene, tetrathiafulvalene, and combinations thereof.
